(19) United States
(12) Patent Application Publication
(10) Pub. No.: US 2011/0193361 A1
(43) Pub. Date: Aug. 11, 2011

(54) Robot arm plate

(76) Inventors: Chia-He Cheng, Taichung County (TW); Ming-Tso Chen, Hsinchu County (TW); Mao-Sheng Hsu, Taoyuan County (TW); Wei-Yen Liu, Hsinchu County (TW)

(21) Appl. No.: 12/702,259

(22) Filed: Feb. 8, 2010

(51) Int. Cl. H01L 21/683; B25J 15/00

(52) U.S. Cl. 294/67.1; 901/30

(57) ABSTRACT

A robot arm plate is provided. The robot arm plate includes a supporting structure and at least a block. The supporting structure includes a first surface to support an object, a second surface and a third surface, wherein the second surface is lower than the first surface, and the third surface is disposed between the first surface and the second surface. The block is disposed on the second surface. The block includes a lateral wall which contacts against the third surface.

### BACKGROUND OF THE INVENTION

1. Field of the Invention

The present invention relates to a robot arm plate, especially to a robot arm plate that is used in a semiconductor manufacturing system.

2. Description of the Prior Art

In semiconductor fabrication, circuits are formed on wafers of a semiconductor material such as silicon. A single crystal of the semiconductor material is sliced into thin wafers and the wafers are transported between various stations, such as processing stations, storage stations, or queuing stations, in the fabrication plant. The fabrication plant must be kept clean to prevent contamination of the semiconductor wafers. The wafers are accordingly handled very carefully in sealed clean-room environments.

Robots are often used to transport the wafers between processing, storage, queuing or other stations. A typical robot arm includes an arm portion that can move vertically or horizontally. A robot arm plate (also called pincette in some semiconductor production equipments) on the end of the arm picks up and places the wafer. Please refer to FIG. 1 and FIG. 2, illustrating the schematic diagrams of a conventional robot arm plate in a semiconductor manufacturing system. As shown in FIG. 1, a wafer 18 is disposed in a chamber 12 of a semiconductor manufacturing system 10 and is supported by a robot arm plate 16. The robot arm plate 16 which is driven by a robot arm portion (not shown) can support and transport the wafer 18 onto a chuck 14 for the subsequent manufacturing processes.

The transporting manner is as following. Firstly, the robot arm plate 16 moves along the direction of arrow A as shown in FIG. 1 (also called “X-direction send”). When the robot arm plate 16 moves to a predetermined position where the robot arm plate 16 corresponds to the chuck 14 vertically, as shown in FIG. 2, the robot arm plate 16 then moves downwardly along the direction of arrow B (Z-direction down), such that the wafer 18 is propped and retained by the chuck 14 which contains a vacuum sucking strength to hold the wafer 18. Subsequently, the robot arm plate 16 moves backwardly in the direction of arrow C (X-direction receive) and leaves the wafer 18 onto the chuck 14. A semiconductor manufacturing process such as an etching process can therefore be applied in the chamber 12.

Please refer to FIG. 3 and FIG. 4, illustrating the schematic diagrams of wafer rupture when the robot arm plate moves downwardly. As shown in FIG. 3, when the robot arm plate 16 moves along the direction A, the wafer 18 will be driven by an inertia force along the direction A which makes the wafer 18 slip outside from the robot arm plate 16. Therefore, the robot arm plate 16 conventionally includes a block 22 disposed on the edge of the robot arm plate 16 so as to prevent the wafer 18 from slipping outside the robot arm plate 16. However, because of the improper design of the conventional block 22, after a certain amount of collisions from the wafer 18, the block 22 becomes loose and then tilts at an angle from the surface of the robot arm plate 16, as shown in FIG. 3. If the raising angle reaches to a degree that is greater than the thickness of the wafer 18, the wafer 18 will be inserted into the tilt space between the robot arm plate 16 and the block 22 and then stuck therein. As a result, when the robot arm plate 16 moves downwardly, as shown in FIG. 4, the wafer 12 will get rupture. It is a serious problem that is needed to be resolved.

### SUMMARY OF THE INVENTION

The present invention therefore provides a robot arm plate that includes a novel supporting structure to avoid the rupture of the wafer in conventional arts.

According to the claimed invention, the robot arm plate includes a supporting structure and at least a block. The supporting structure includes a first surface to support an object, a second surface and a third surface, wherein the second surface is lower than the first surface, and the third surface is disposed between the first surface and the second surface. The block is disposed on the second surface of the supporting structure. The block includes a lateral wall which contacts against the third surface.

Because the block is disposed on the second surface and contacts against the third surface of the supporting structure, the tilt phenomenon cause by the impact from the wafer can be prevented and the reliability of the wafer manufacturing process can be increased.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 illustrate the schematic diagrams of a conventional robot arm plate in a semiconductor manufacturing system.

FIG. 3 and FIG. 4 illustrate the schematic diagrams of wafer rupture when the Z-direction down.

FIG. 5 illustrates a cross sectional schematic diagram of the preferred embodiment of the robot arm plate in the present invention.

FIG. 6 illustrates a schematic diagram of another preferred embodiment of the robot arm plate in the present invention.

FIG. 7 illustrates a schematic diagram of another preferred embodiment of the robot arm plate in the present invention.

FIG. 8 illustrates the schematic diagram of another preferred embodiment of the robot arm plate in the present invention.

FIG. 9 illustrates a 3D schematic diagram of the robot arm plate in the present invention.

### DETAILED DESCRIPTION

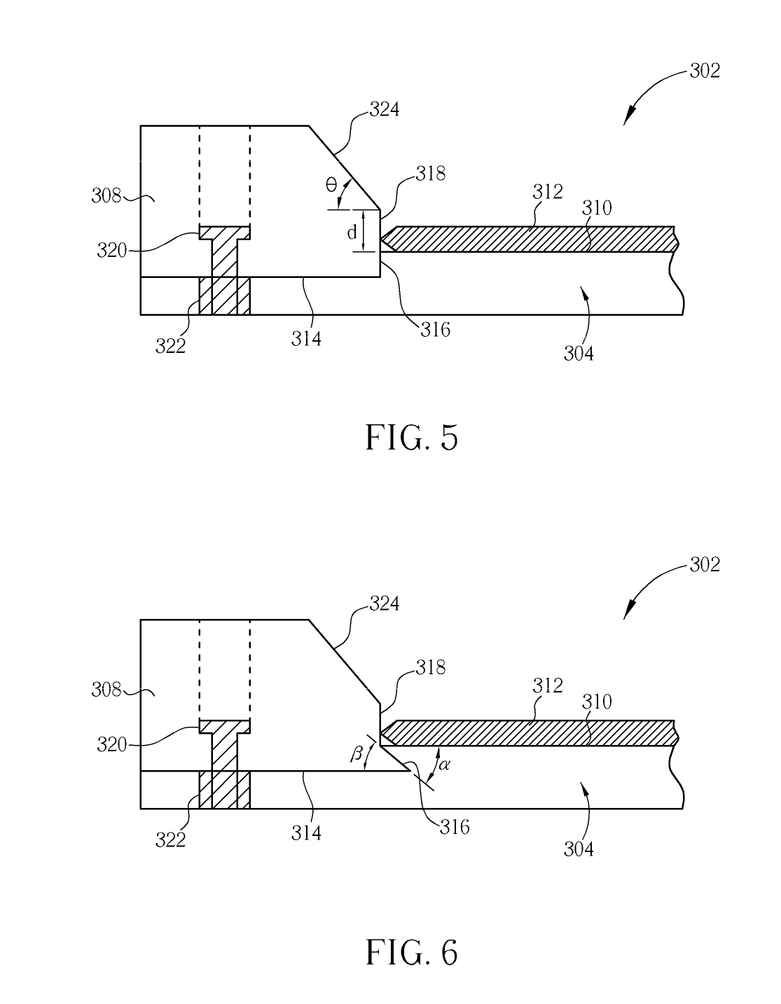

In order to prevent the block tilting phenomenon which may brings to wafer rupture in conventional arts, the robot arm plate in the present invention includes a third surface for the block to dispose thereagainst. Please refer to FIG. 5, illustrating a cross sectional schematic diagram of the preferred embodiment of the robot arm plate in the present invention. As shown in FIG. 5, the robot arm plate 302 includes a supporting structure 304 and a block 308, all of which are disposed on the upper side of the robot arm plate 302. The supporting structure 304 includes a first surface 310 to support an object, for example, a wafer 312. The first surface 310 is usually horizontal such that the wafer 312 can be hold in balance during transportation.

The supporting structure 304 further includes a second surface 314 and a third surface 316. The second surface 314 is lower than the first surface 310 and is substantially parallel to the first surface 310. The third surface 316 is disposed between the first surface 310 and the second surface 314, meaning that one side of the third surface 316 is adjacent to the first surface 310 and the other side is adjacent to the second surface 314. In one preferred embodiment, the first surface 310 and the third surface 316 are perpendicular; the second surface 314 and the third surface 316 are perpendicular, thereby forming a vertical structure.

The block 308 is disposed on the second surface 314 of the supporting structure 304. The block 308 can be fixed onto the supporting structure 304 in any manner. In one embodiment as shown in FIG. 5, the robot arm plate 302 further includes a screw 320. The block 308 can be fixed on the second surface 314 of the supporting structure 304 by the screw 320. Correspondingly, the robot arm plate 302 includes a screw nut 322 disposed in the supporting structure 304 below the second surface 314 and the screw 320 can be inserted into the screw nut 322 to provide greater stability. The screw 320 and the screw nut 322 can be made of metal, ceramics or other suitable materials that is not easy to deform, but should not be limited thereto. In addition to the screw manner, the block 308 can also be fixed onto the supporting structure 304 in other manners, for example, by an adhesive or an extra-fixing-component

As shown in FIG. 5, the block 308 includes a lateral wall 318 which contacts against the third surface 316 of the supporting structure 304. It is one salient feature in the present invention that when the block 308 is collided by the wafer 312 during the “X-direction send”, the third surface 316 of the supporting structure 304 can generate a counter force to prevent the block 308 tilt at an angle from the second surface 314, making the block 308 fixed securely onto the robot arm plate 302. In a preferred embodiment, the second surface 314 and the third surface 316 can include a tough surface, for example, by forming a plurality of micro-structures, or spraying some tough particles thereon to increase the friction strength.

To provide a better buffer environment when the wafer 312 collides with the block 308, the hardness of the block 308 is preferably smaller than that of the wafer 312. For instance, the material of the block 308 may include resin or plastic. However, the material of the block 308 can be altered according to the transported object. The principle is that the block 308 can stop the object when moving and can function as a buffer region.

Because the lateral wall 318 of the block 308 is used to stop the wafer 318 and bear its collision, the lateral wall 318 should be able to contact the wafer 312. That is, the height of the lateral wall 318 protruding from the first surface 310 (as the length d in FIG. 5) is greater than the thickness of the wafer 312 (or the object), so the block 308 can provide excellent buffer environment when the wafer 312 leans against the block 308. Moreover, the block 308 further includes an inclined wall 324 adjacent to the lateral wall 318. More precisely, the inclined wall 324 is disposed on the top portion of the block 308 and includes an inclined angle θ that is between 0 to 90 degrees. The inclined wall 324 can help the wafer 312 sliding back to the first surface 310 of the supporting structure 304. For example, in some situations, if the impact strength is too large, the wafer 312 may leap over the lateral wall 318 and fall onto the inclined wall 324. The inclined wall 324 can therefore help the wafer 312 sliding back to the first surface 310. Or, in another situation, when finishing the manufacturing processes, the wafer 312 is subjected to the next process, the robot arm plate 302 therefore stretches and moves upwardly to pick up the wafer 312. If the position of the wafer 312 and the robot art plate 302 do not match well while the robot arm plate 302 picks up the wafer 312 from the chuck, the wafer 312 may falls on the inclined wall 324. The wafer 312 can slide back along the inclined wall 324 and back to the first surface 310 of the supporting structure 304. In the preferred embodiment, the inclined wall 324 has a smooth surface so the wafer 312 is easy to slide back when leaping on the inclined wall 324.

Please refer to FIG. 6, illustrating a schematic diagram of another preferred embodiment of the robot arm plate in the present invention. As shown in FIG. 6, the supporting structure 304 includes a tilt structure instead of a vertical structure. That is, the angle α define by the first surface 310 and the third surface 316 can be between 0 to 90 degrees, preferably 30 to 90 degrees, being an acute angle or a right angle. The angle β defined by the second surface 314 and the third surface 316 can also be between 0 to 90 degrees, preferably 30 to 90 degrees, being an acute angle or a right angle as well. It is therefore a tilt structure of the supporting structure 304 is provided. The lower portion of the lateral wall 318 correspondingly protrudes into the tilt structure and contacts against the third surface 316. The tilt structure of the supporting structure 304 provides an even better stability, making the block 308 fixing onto the supporting structure 304 against the collision from the wafer 312.

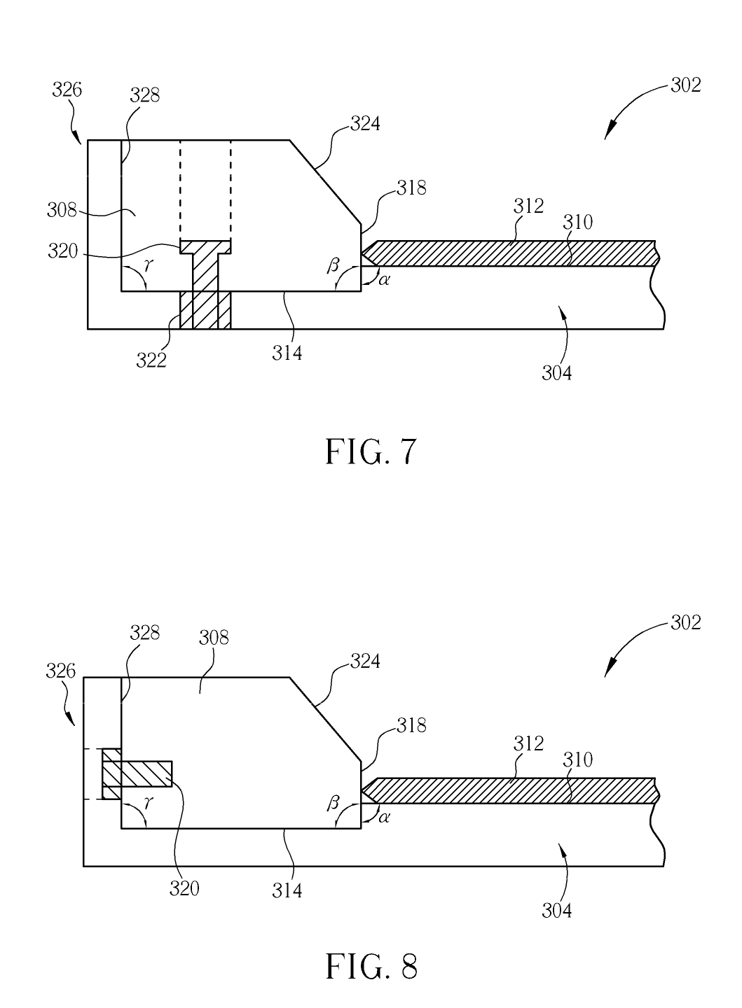

Please refer to FIG. 7, illustrating a schematic diagram of another preferred embodiment of the robot arm plate in the present invention. As shown in FIG. 7, the robot arm plate 302 further includes a protruding structure 326 extending upwardly from the second surface 314 of the supporting structure 304. The protruding structure 326 may be monolithic with the supporting structure 304 or an extra component. The protruding structure 326 includes a forth surface 328 on the side facing the block 308 so the block 308 can contact against the forth surface 328. The second surface 314, the third surface 316 and the forth surface 328 therefore define a recess where the block 308 can be installed therein, providing more stability for the block 308. The angle γ defined by the second surface 314 and the forth surface 328 is preferably a right angle, but could be an acute angle or an obtuse angle. It is understood that the angle α, the angle β and the angle γ can be arranged arbitrarily to provide different embodiments. The entire embodiments are not shown for the sake of simplicity.

As shown in FIG. 7, the block 308 is fixed on the second surface 314 of the supporting structure 304 by the screw 320 and the screw nut 322. However, the present embodiment provides another fixing manner. Please refer to FIG. 8, illustrating the schematic diagram of another preferred embodiment of the robot arm plate in the present invention. As shown in FIG. 8, the screw 320 is disposed through the forth surface 328 and screwed into the block 308. As in conventional arts, when the screw 320 and the corresponding screw nut 322 are disposed within the second surface 314 of the supporting structure 304, it is possible that the portion of the supporting structure 304 around the screw nut 322 may be broken when suffering a serious collision from the wafer 312. As a result, this embodiment provides a fixing manner that no additional screw nut is needed in the block 308 and the screw 320 can be directly screwed into the block 308 through the lateral side beneath the forth surface 328, providing a more reliable fixing manner.

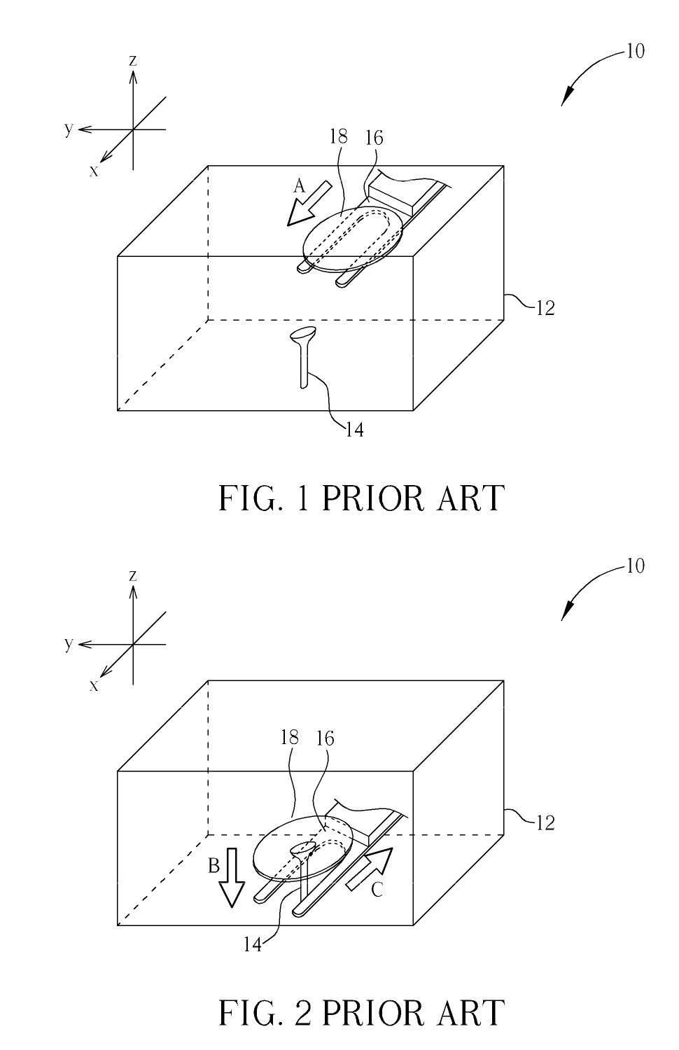

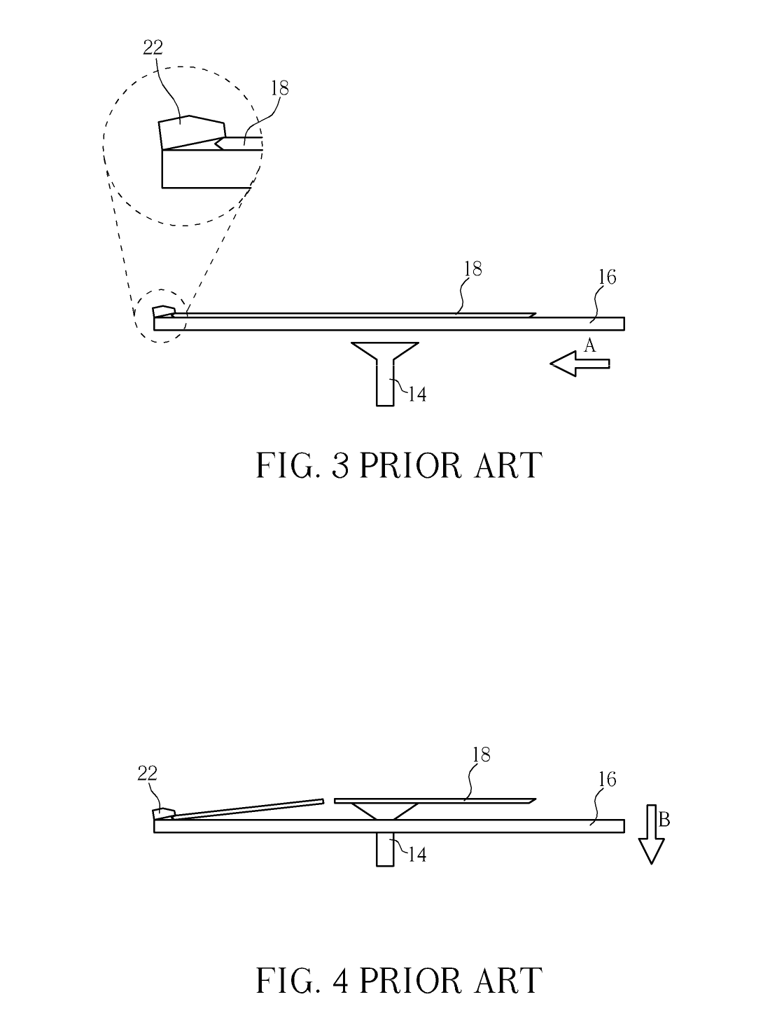

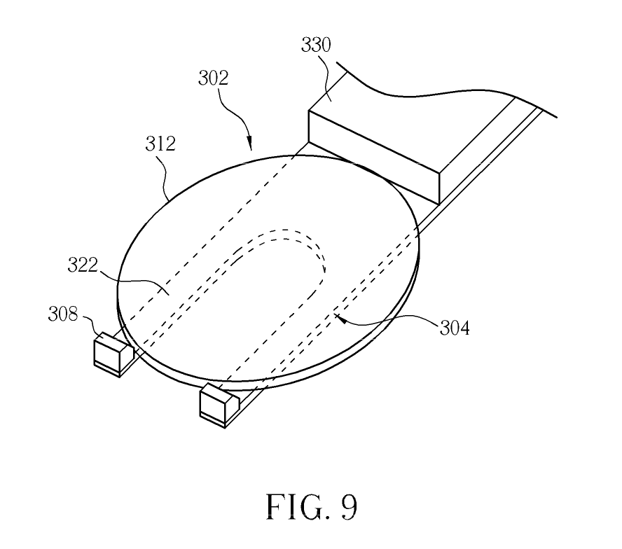

Please refer to FIG. 9, illustrating a 3D schematic diagram of the robot arm plate in the present invention. As shown in FIG. 9, the robot arm plate 302 can further connect to a robot arm 330. The robot arm 330 can control the moving pathway so the wafer 302 can be transported to a place where a semiconductor manufacture process is performed, for example, the chamber 12 in the semiconductor manufacturing system 10 as shown in FIG. 1. Besides, the supporting structure 304 includes two branches 332 disposed on the other side relative to the robot arm 330. The block 308 is disposed on the edge of each branch 322. Thus, the gap between the two branches 332 can provides a space for the chuck (as the chuck 14 in FIG. 2) to hold the wafer 312. It is understood that the robot arm plate 332 may includes more than two branches 332, depending on different purposes of product designs.

In light of above, the present invention provides a robot arm plate with a novel supporting structure. The block contacts against the third surface of the supporting structure so the block may not tilt up even under serious collision by the wafer. The invention further provides a protruding structure and a novel screw manner via the protruding structure to firmly fix the block onto the supporting structure. The robot arm plate may not only be applied to semiconductor manufacture systems but also can be applied in other fields to support and transport an object, for example, a vehicle module. The robot arm plate in the present invention therefore provides a wide application and is useful in a variety of fields.

Those skilled in the art will readily observe that numerous modifications and alterations of the device and method may be made while retaining the teachings of the invention.

1. A robot arm plate, the robot arm plate comprising:
a supporting structure comprising a first surface, a second surface and a third surface, wherein the second surface is lower than the first surface, and the third surface is disposed between the first surface and the second surface; and
at least a block disposed on the second surface of the supporting structure, wherein the block comprises a lateral wall which contacts against the third surface.

2. The robot arm plate as in claim 1, wherein the angle of the first surface and the third surface is between 0 to 90 degrees.

3. The robot arm plate as in claim 1, wherein the angle of the second surface and the third surface is between 0 to 90 degrees.

4. The robot arm plate as in claim 1, further comprising a screw, wherein the block is fixed on the second surface by the screw.

5. The robot arm plate as in claim 4, further comprising a screw nut disposed below the second surface, wherein the screw is inserted into the screw nut.

6-11. (canceled)

12. The robot arm plate as in claim 1, wherein the block comprises resin or plastic.

13. The robot arm plate as in claim 1, wherein the block comprises an inclined surface disposed adjacent to the lateral wall.

14. The robot arm plate as in claim 13, wherein the inclined surface comprises a smooth surface.

15. The robot arm plate as in claim 1, wherein the supporting structure comprises at least two branches, wherein at least one branch comprises a block disposed on the edge of the branch.

16. The robot arm plate as in claim 1, wherein the robot arm plate is used in a semiconductor manufacturing system for supporting a wafer.

17. The robot arm plate as in claim 16, wherein the wafer is disposed on the first surface.

18. The robot arm plate as in claim 16, wherein the height of the lateral wall protruding from the first surface is greater than the thickness of the wafer.

19. The robot arm plate as in claim 16, wherein the hardness of the block is smaller than that of the wafer.

20. The robot arm plate as in claim 16, wherein the semiconductor system comprises a robot arm which connects to another side of the supporting structure against the block.
